(19) United States
(12) Patent Application Publication
(10) Pub. No.: US 2025/0087092 A1
(43) Pub. Date: Mar. 13, 2025

(54) THREE-DIMENSIONAL SIMULATION METHOD AND THREE-DIMENSIONAL SIMULATION APPARATUS

(71) Applicants: SAMSUNG E&A CO., LTD., Seoul (KR); Morai Inc., Seoul (KR)

(72) Inventors: Jun Chul HWANG, Seoul (KR); Sung Il KIM, Seoul (KR); Yong Ho AHN, Seoul (KR); Jae Hun CHOI, Seoul (KR); Taek Sun LEE, Seoul (KR); Hwang JEON, Seoul (KR); Jun HONG, Seoul (KR); Ji Won JUNG, Seoul (KR)

(73) Assignees: SAMSUNG E&A CO., LTD., Seoul (KR); Morai Inc., Seoul (KR)

(21) Appl. No.: 18/528,138

(22) Filed: Dec. 4, 2023

(30) Foreign Application Priority Data
Sep. 13, 2023 (KR) 10-2023-0121917

(51) Int. Cl. G08G 1/16; G06T 17/20; G08G 1/01

(52) U.S. Cl. CPC G08G 1/166; G06F 30/20; G06T 17/20; G08G 1/0112; G08G 1/0125; G01C 21/34; G05D 1/2465

(57) ABSTRACT

Disclosed are a three-dimensional (3D) simulation method and a 3D simulation apparatus. The 3D simulation method disclosed herein includes a step (S20) of separating point cloud data including a road, an obstacle, and a cargo transportation route into road data and obstacle data, a step (S40) of converting the road data into road mesh data, and converting the obstacle data into obstacle mesh data, a step (S60) of constructing a virtual environment by merging the road mesh data with the obstacle mesh data, a step (S80) of loading a specific cargo transportation route to the virtual environment, a step (S100) of loading a 3D transport truck and a 3D cargo to a predetermined point of the cargo transportation route, and a step (S120) of performing a route survey simulation while virtually driving the 3D transport truck and the 3D cargo along the cargo transportation route.

### CROSS-REFERENCE TO RELATED APPLICATION

This application is based on and claims priority under 35 U.S.C. § 119 to Korean Patent Application No. 10-2023-0121917, filed on Sep. 13, 2023, in the Korean Intellectual Property Office, the disclosure of which is incorporated by reference herein in its entirety.

### BACKGROUND

### 1. Field

The disclosure relates to a three-dimensional (3D) simulation method and a 3D simulation apparatus. More specifically, the disclosure relates to a 3D simulation method and a 3D simulation apparatus, which find a minimum interference route among one or more cargo transportation routes that exist between a starting point and an end point and determine in advance a maximum transportable cargo size through the minimum interference route.

### 2. Description of the Related Art

As the logistics industry of large-scale special cargo continues to grow and large-scale construction projects in developing countries continue to grow, conventionally, cargo transportation routes are typically constructed manually in an extremely time-consuming manner to find methods to reduce the enormous costs of transporting massive and heavy cargo and overcome interference with obstacles.

For example, conventionally, heavy cargo transportation companies directly survey cargo transportation routes by using photographing equipment; however, this method has a number of limitations in that the data thus acquired alone require cargo transportation routes to be marked manually, automatic recognition of interfering obstacles is difficult, and the maximum transportable cargo size can only be identified through multiple manual operations.

### SUMMARY

Provided is a three-dimensional (3D) simulation method that can find a minimum interference route among one or more cargo transportation routes that exist between a starting point and an end point, and determine in advance a maximum transportable cargo size via the minimum interference route.

Provided is a 3D simulation apparatus that can find a minimum interference route among one or more cargo transportation routes that exist between a starting point and an end point, and determine in advance a maximum transportable cargo size via the minimum interference route.

Additional aspects will be set forth in part in the description which follows and, in part, will be apparent from the description, or may be learned by practice of the presented embodiments of the disclosure.

According to an aspect of the disclosure, a 3D simulation method includes
a step (S20) of separating point cloud data including a road, an obstacle, and the cargo transportation route into road data and obstacle data;
a step (S40) of converting the road data to road mesh data, and converting the obstacle data to obstacle mesh data;
a step (S60) of constructing a virtual environment by merging the road mesh data with the obstacle mesh data;
a step (S80) of loading a specific cargo transportation route to the virtual environment;
a step (S100) of loading a 3D transport truck and a 3D cargo to a predetermined point of the cargo transportation route of the virtual environment; and
a step (S120) of performing route survey simulation while virtually driving the 3D transport truck and the 3D cargo along the cargo transportation route.

The 3D simulation method may further include, prior to the step (S20), a step (S10) of acquiring point cloud data that include a road, an obstacle, and a cargo transportation route with respect to all possible cargo transportation routes.

In the step (S20), the obstacle may include all objects excluding the road.

The step (S10) may be performed by using a mobile mapping system (MMS).

The MMS may include a global positioning system (GPS), an inertial measurement unit (IMU), a distance measuring instrument (DMI), a light detection and ranging (LiDAR), a high-performance camera, or a combination thereof.

In the step (S40), the road mesh data may be one-sided mesh data, and the obstacle mesh data may be two-sided mesh data.

The 3D simulation method may further include a step (S50) of rendering the road mesh data and the obstacle mesh data between the step (S40) and the step (S60).

The 3D simulation method may further include a step (S90) of editing the loaded cargo transportation route between the step (S80) and the step (S100).

In the step (S120), the route survey simulation may examine collision information between the obstacle and at least one of the 3D transport truck and the 3D cargo during virtual driving of the 3D transport truck, wherein the collision information may include collision location information, non-collision location information, a collision area of the 3D transport truck, a collision area of the 3D cargo, a type of a collision obstacle, a type of non-collision obstacle, a collision area of a collision obstacle, or a combination thereof.

The 3D simulation method may further include, after the step (S120), a step (S140) of editing the collision information, and a step (S160) of storing the edited collision information.

The step (S140) may include a step (S140-1) of listing up the collision information, a step (S140-2) of modifying the collision information, a step (S140-3) of changing the shape or size of the 3D transport truck or the 3D cargo so as to enable collision avoidance, and a step (S140-4) of converting a collision obstacle in the listed-up collision information to a non-collision obstacle by reflecting the result of the step (S140-3).

The 3D simulation method may further include loading the stored collision information after the step (S160).

The 3D simulation method may further include a step of repeating the steps (S80) to (S120) for each of other cargo transportation routes, other than the specific cargo transportation route.

The 3D simulation method may further include a step (S130) of finding a cargo transportation route with the smallest number of collisions.

According to another aspect of the disclosure, a 3D simulation apparatus is configured to execute the 3D simulation method using a computer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart showing a three-dimensional (3D) simulation method according to an embodiment;

FIG. 2 is a diagram illustrating a point cloud data acquisition method performed in a step (10) of the 3D simulation method shown in FIG. 1;

FIG. 3 is a diagram illustratively showing an output of steps (20) to (60) of the 3D simulation method shown in FIG. 1; and

FIG. 4 is a diagram showing a display screen of a 3D simulation apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein.

Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, a three-dimensional (3D) simulation method and apparatus according to an embodiment will be described in greater detail with reference to the drawings.

As used herein, “point cloud” refers to a set of points belonging to a certain coordinate system. In a 3D coordinate system, points are usually defined by x, y, and z coordinates, and are often used to represent a surface of an object.

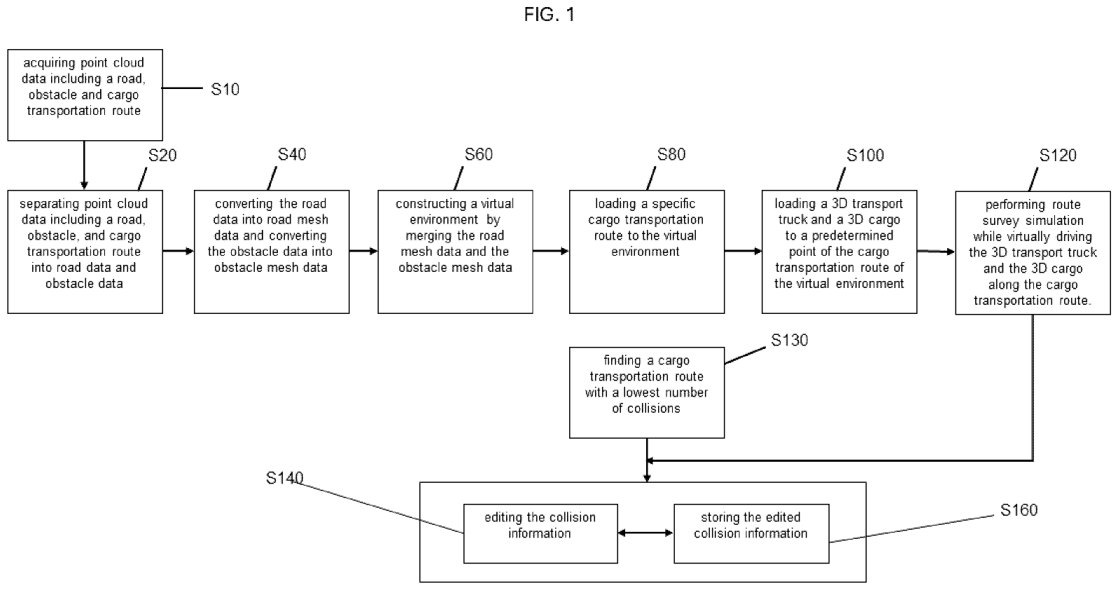

FIG. 1 is a flowchart showing a 3D simulation method according to an embodiment.

Referring to FIG. 1, a 3D simulation method according to an embodiment may include: a step (S20) of separating point cloud data including a road, an obstacle, and the cargo transportation route into road data and obstacle data; a step (S40) of converting the road data into road mesh data and converting the obstacle data into obstacle mesh data; a step (S60) of constructing a virtual environment by merging the road mesh data and the obstacle mesh data; a step (S80) of loading a specific cargo transportation route to the virtual environment; a step (S100) of loading a 3D transport truck and a 3D cargo to a predetermined point of the cargo transportation route of the virtual environment; and a step (S120) of performing route survey simulation while virtually driving the 3D transport truck and the 3D cargo along the cargo transportation route.

The 3D simulation method may further include, prior to the step (S20), a step (S10) of acquiring point cloud data that include a road, an obstacle, and a cargo transportation route with respect to all possible cargo transportation routes.

The cargo transportation route may include one or more roads that are passably connected to each other.

The step (S10) may be performed by using a mobile mapping system (MMS).

The MMS may include a global positioning system (GPS), an inertial measurement unit (IMU), a distance measuring instrument (DMI), a light detection and ranging (LiDAR), a high-performance camera, or a combination thereof.

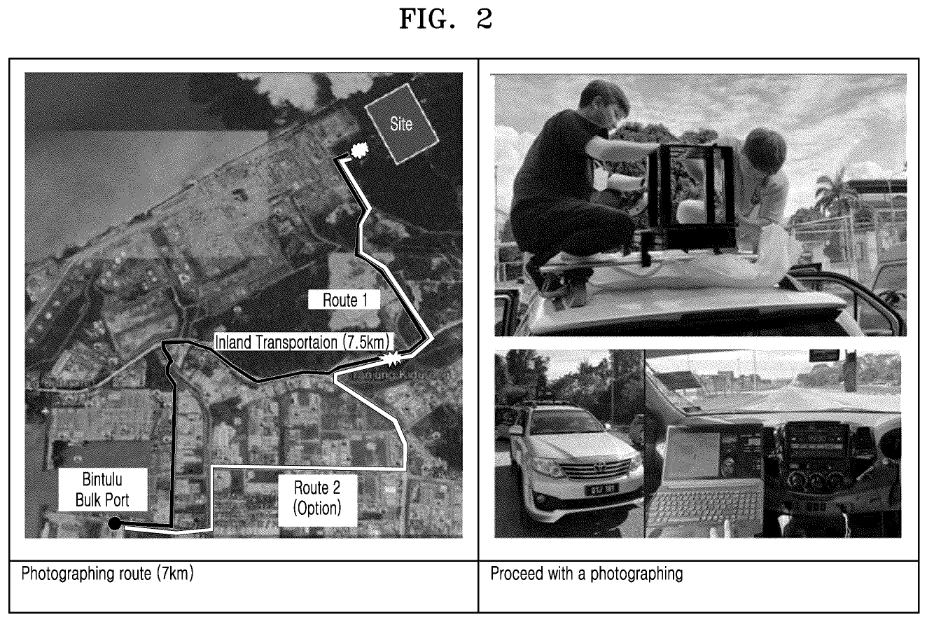

FIG. 2 is a diagram illustrating a point cloud data acquisition method performed in a step (10) of the 3D simulation method shown in FIG. 1.

Referring to FIG. 2, with respect to Route 1 and Route 2, the MMS may be used to photograph roads and obstacles to acquire point cloud data including roads, obstacles, and cargo transportation routes. The acquired point cloud data may be stored on a computer.

The acquired point cloud data may have a date, a time, a node number, a latitude value, and a longitude value. Further, in the acquired point cloud data, the point cloud data for a specific object (a road or an obstacle) may have a three-dimensional coordinate value for each point, a width value of the object, a height value of the object and/or a length value of the object, and the like.

The step (S20) may include a step of receiving the point cloud data acquired in the step (10).

In the step (S20), the obstacle may include all stationary objects, excluding the road. Moving objects such as cars, two-wheeled vehicles, and people may not be included in the obstacle. For example, the obstacle may include street trees (trees), traffic lights, signs, electric poles, buildings, bridges, overpasses, tunnels, or a combination thereof.

The step (S20), as in the step (S40) described later, may be a step necessary for converting the road data and the obstacle data into mesh data, respectively.

Additionally, the 3D simulation method may further include, between the step (S10) and the step (S20), a step (S15) of removing noise from the point cloud data acquired in the step (10). The noise may include unnecessary points or moving objects (vehicles, two-wheeled vehicles, people, etc.).

In the step (S40), the road mesh data may be one-sided mesh data, and the obstacle mesh data may be two-sided mesh data. The one-sided mesh data refers to data in which only the point data corresponding to a top surface of a road is converted to mesh without converting point data corresponding to a bottom surface of the road from point data of the road to mesh, and the two-sided mesh data refers to data in which all of point data of an obstacle are converted to mesh. As such, by separating the road data and the obstacle data and converting the same into mesh data, respectively, the mesh conversion computation speed may be drastically improved. Specifically, converting the road data and the obstacle data to mesh data, respectively, may significantly increase the mesh conversion computation speed compared to converting the road data and the obstacle data into two-sided mesh data at once without separating the road data and the obstacle data from each other.

Even if the road mesh data is converted to one-sided mesh data rather than two-sided mesh data, there is no problem in implementing the 3D simulation method of the present invention, and the mesh conversion computation speed can be improved. However, the obstacle mesh data should be converted to two-sided mesh data, not one-sided mesh data, even if the mesh conversion computation speed is slowed; this is because when it comes to specifying an obstacle, when any part of the obstacle is omitted, an obstacle collision test cannot be carried out accurately. That is, because it is impossible to predict which part of the obstacle the 3D transport truck or cargo collides with, the entire shape of the object should be implemented in a mesh form from all directions.

The virtual environment constructed in the step (S60) may be an environment imitating a real environment, and may be an environment that not only has a similar shape to the real environment, but also is substantially identical or extremely similar to the real environment in terms of 3D location information.

Additionally, the 3D simulation method may further include a step (S50) of rendering the road mesh data and the obstacle mesh data between the step (S40) and the step (S60).

The step (S50) may be a step of coloring the road mesh data and/or the obstacle mesh data, expressing a perspective by adjusting brightness and the intensity of saturation, and/or increasing resolution.

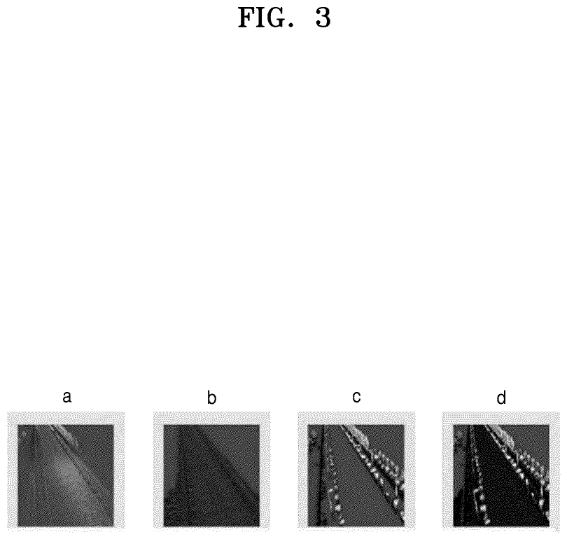

FIG. 3 is a diagram illustratively showing an output of the steps (S20) to (S60) of the 3D simulation method shown in FIG. 1.

Referring to FIG. 3, FIG. 3A is a diagram showing a state in which the point cloud data acquired in the step (S20) is separated into road data and obstacle data, FIG. 3B is a diagram showing a state in which the road data is converted to road mesh data (one-sided mesh data) in the step (S40), FIG. 3C is a diagram showing a state in which the obstacle data in the step (S40) is converted to obstacle mesh data (two-sided mesh data), and FIG. 3D is a diagram showing a state in which the road mesh data and the obstacle mesh data are merged in the step (S60).

The step (S80) may be a step of activating, visualizing, or displaying a specific cargo transportation route among one or more cargo transportation routes included in the point cloud data of the step (S20).

In the step (S100), the 3D mobile truck and the 3D cargo may each have 3D position coordinates and 3D size information.

Additionally, in the step (S100), the type, shape, and size of the 3D cargo along with the type, shape, and size of the 3D transport truck may be freely adjusted and finally set.

In the step (S100), the 3D transport truck may be a 3D model taken after a self-propelled modular transporter (SPMT), but is not limited thereto. The SPMT, which is an equipment used for transporting heavy objects, is self-powered and self-driving as the name suggests, and is a transportation equipment that is manufactured to be modular and thus can flexibly meet a variety of needs.

Also, in the step (S100), the 3D cargo may include various modules or large columns.

Additionally, in the step (S100), only one unit of the 3D transport truck may be loaded, or a plurality of the 3D transport truck may be loaded and connected in a row, or a plurality of the 3D transport truck may be loaded and connected in a horizontal row. Further, the 3D cargo may be loaded in a shape and size appropriately loadable on the loaded 3D transport truck, and then loaded on the 3D transport truck.

Additionally, in the step (S100), the 3D transport truck and the 3D cargo may be produced using a 3D modeling program (e.g., 3ds MAX) and then loaded into the virtual environment via a motionalization process using a motionalization program developed by the present inventors.

Additionally, the 3D simulation method may further include a step (S90) of editing the loaded cargo transportation route, between the step (S80) and the step (S100).

The step (S90) may be a step of modifying at least a part of the loaded cargo transportation route or changing a cargo transportation lane. As an example, the step (S90) may be a step of connecting at least a portion of the loaded cargo transportation route with at least a portion of another cargo transportation route. As another example, the step (S90) may be a step of changing the cargo transportation lane from 2 lanes to 3 lanes, or from 3 lanes to 2 lanes.

The step (S120) may be a step of examining and recording collision information between the obstacle and at least one of the 3D transport truck and the 3D cargo.

The collision information may include collision location information, non-collision location information, a collision part of the 3D transport truck, a collision part of the 3D cargo, a type of a collision obstacle, a type of a non-collision obstacle, a collision part of a collision obstacle, or a combination thereof.

Additionally, the 3D simulation method may further include, after the step (S120), a step (S140) of editing the collision information and a step (S160) of storing the edited collision information.

The step (S140) may include a step (S140-1) of listing up the collision information, a step (S140-2) of modifying the collision information, a step (S140-3) of changing the shape or size of the 3D transport truck or the 3D cargo so as to enable collision avoidance, and a step (S140-4) of, by reflecting the result of the step (S140-3), converting a collision obstacle in the listed-up collision information to a non-collision obstacle.

The step (S140-2) may include a step of considering some of the obstacles included in the collision information as non-obstacles and automatically removing the same. For example, among the obstacles included in the collision information, destructible obstacles such as street trees (trees), streetlights, signs, and electric poles, may be considered as non-obstacles and automatically removed.

Further, the 3D simulation method may further include, after the step (S160), a step of loading the collision information stored in the step (S160). Accordingly, a user may retrieve and use the collision information stored in the step (S160) at any time when necessary.

The 3D simulation method may further include a step of repeating the steps (S80) to (S120) or the steps (S80) to (S160) for each of other cargo transportation routes other than the specific cargo transportation route. Such repeating step may be performed immediately after the step (S120), may be performed at any point between the step (S130) and the step (S160), or may be performed after the step (S160).

The 3D simulation method may further include a step (S130) of finding a cargo transportation route with a lowest number of collisions (also referred to as “minimum interference route”).

The step (S130) may be performed immediately after the step (S120), may be performed at any point between the step (S130) and the step (S160), or may be performed after the step (S160).

The 3D simulation method according to an embodiment, having the above configuration, may identify all obstacles on a cargo transportation route and removes destructible obstacles, and when transportation of the 3D cargo is difficult due to stationary obstacles, may enable the transportation by changing the shape of the 3D cargo or reducing the size of the 3D cargo. Additionally, the 3D simulation method may be configured such that, obstacles are listed up whenever an obstacle appears, and the listed-up obstacles (i.e., collision obstacles) are gradually eliminated by modifying the shape of the 3D cargo or reducing the size of the 3D cargo. Additionally, the 3D simulation method may be expected to be more useful as obstacles such as “overpasses of sloping roads” become more complex.

Another aspect of the disclosure provides a 3D simulation apparatus configured to execute the 3D simulation method by using a computer.

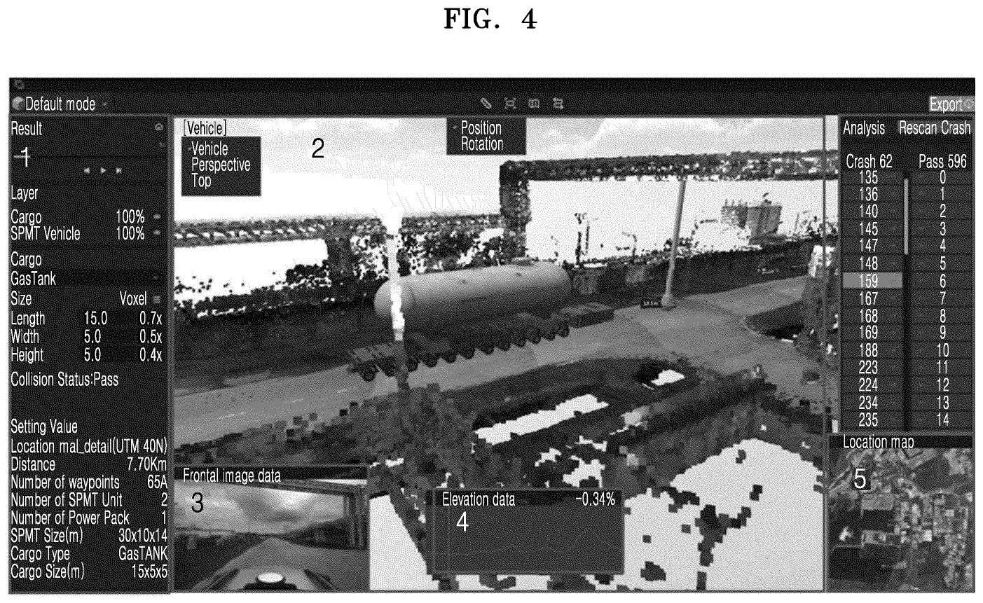

FIG. 4 is a diagram showing a display screen of a 3D simulation apparatus according to an embodiment.

Referring to FIG. 4, a display screen of the 3D simulation apparatus may be configured to display overall progress information 1, a 3D map screen 2, an actual photograph 3, a road slope 4, a route map 5, and the 3D cargo collision check result 6.

The 3D simulation method and the 3D simulation apparatus according to embodiments, having the above configuration, may have advantages as shown in Table 1 below, compared to conventional route survey methods.

TABLE 1

| | | 3D simulation method and |
|---|---|---|
| Item | Conventional route survey method | 3D simulation apparatus |
| Method of conducting | Conduct a cargo transportation | Conduct a cargo |
| cargo transportation | route survey by using vehicle | transportation route survey |
| route survey | movement, photographs, and maps | by using vehicles equipped |
| | | with Mobile Mapping System |
| | | (MMS) |
| Advantages vs. | High costs and long-time | Fast photographing and |
| Disadvantages | consumption when surveying long- | data acquisition are possible |
| | distance cargo transportation | through autonomous |
| | routes | performance |
| | A change in critical cargo size | A single photographing |
| | may require re-survey even after | may secure permanent |
| | survey is once complete | cargo transportation route |
| | Limitations exist in reading cargo | maps and accurate data on |
| | transportation route survey results, | obstacles |
| | such as photographs and maps, | Interference results may be |
| | and identifying obstacle | confirmed through |
| | interferences | simulation by freely |
| | | adjusting the shape and size |
| | | of cargo along the acquired |
| | | cargo transportation routes |

Additionally, when using the 3D simulation method and the 3D simulation apparatus according to embodiments, having the above configuration, a detailed case study according to module size may be possible, and an example of such a case study is shown in Table 2 below.

TABLE 2

| | Case 1 | Case 2 | Case 3 |
|---|---|---|---|
| Item | (Large size) | (Medium size) | (Small size) |
| Module size | 45 mL × 17 | 35 mL × 15 | 30 mL × 10 |
| | mW × 15 mH | mW × 10 mH | mW × 7 mH |
| Number of collision | 35 | 15 | 4 |
| obstacles | | | |
| Expected | US$ 530,000 | US$ 270,000 | US$ 75,000 |
| overcoming cost | | | |

Although the disclosure has been described with reference to the drawings, these embodiments are merely exemplary, and those skilled in the art shall understand that various modifications and equivalent other embodiments are possible therefrom. Therefore, the full scope of technical protection for the disclosure shall be defined by the technical concept of the following claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

1. A three-dimensional (3D) simulation method comprising:
a step (S10) of acquiring point cloud data including a road, an obstacle, and at least one cargo transportation route by a mobile mapping system (MMS);
a step (S20) of separating, by a 3D simulation apparatus, point cloud data including the road, the obstacle, and the at least one cargo transportation route into road data and obstacle data;
a step (S40) of (1) converting, by the 3D simulation apparatus, the road data into one-sided road mesh data by converting only point data corresponding to a top surface of a road to mesh without converting point data corresponding to a bottom surface of the road, and (2) converting, by the 3D simulation apparatus, the obstacle data into two-sided obstacle mesh data by converting all point data of an obstacle to mesh;
a step (S60) of constructing, by the 3D simulation apparatus, a virtual environment by merging the road mesh data and the obstacle mesh data;
a step (S80) of loading, by the 3D simulation apparatus, a specific cargo transportation route to the virtual environment;
a step (S100) of loading, by the 3D simulation apparatus, via a motionalization process using a motionalization program, a 3D transport truck and a 3D cargo to a predetermined point of the specific cargo transportation route of the virtual environment; and
a step (S120) of driving, by the 3D simulation apparatus, the 3D transport truck and the 3D cargo along the specific cargo transportation route, to perform performing route survey simulation.

2. (canceled)

3. The 3D simulation method of claim 1, wherein, in the step (S20), the obstacle includes all objects excluding the road.

4. (canceled)

5. The 3D simulation method of claim 1,
wherein the MMS comprises a global positioning system (GPS), an inertial measurement unit (IMU), a distance measuring instrument (DMI), a light detection and ranging (LiDAR), a high-performance camera, or a combination thereof.

6. (canceled)

7. The 3D simulation method of claim 1, further comprising, between the step (S40) and the step (S60), a step of rendering the road mesh data and the obstacle mesh data.

8. The 3D simulation method of claim 1, further comprising, between the step (S80) and the step (S100), a step of editing the loaded specific cargo transportation route.

9. The 3D simulation method of claim 1,
wherein the route survey simulation in the step (S120) is to examine collision information between the obstacle and at least one of the 3D transport truck and the 3D cargo during virtual driving of the 3D transport truck, wherein the collision information comprises collision location information, non-collision location information, a collision area of the 3D transport truck, a collision area of the 3D cargo, a collision area of a collision obstacle, or a combination thereof.

10. The 3D simulation method of claim 9, further comprising, after the step (S120), a step (S140) of editing the collision information and a step (S160) of storing the edited collision information.

11. The 3D simulation method of claim 10,
wherein the step (S140) further includes listing up the collision information, modifying the collision information, changing a shape or a size of the 3D transport truck or the 3D cargo so as to enable collision avoidance, and converting the collision obstacle in the listed-up collision information to a non-collision obstacle.

12. The 3D simulation method of claim 10, further comprising, after the step (S160), a step of loading the stored collision information.

13. The 3D simulation method of claim 1, further comprising a step of repeating the steps (S80) to (S120) for each cargo transportation route of the at least one cargo transportation route, other than the specific cargo transportation route.

14. The 3D simulation method of claim 13, further comprising a step (S130) of finding a cargo transportation route, of the at least one cargo transportation route, with a least number of collisions.

15. A three-dimensional (3D) simulation apparatus configured to execute the 3D simulation method according to claim 1 by using a computer.
